(19) United States
(12) Patent Application Publication
(10) Pub. No.: US 2004/0100783 A1
(43) Pub. Date: May 27, 2004

(54) Adaptive backplane system for electronic cards

(76) Inventor: Niv Amit, Kfar Malal (IL)

Correspondence Address: WELSH & FLAXMAN LLC, 2450 CRYSTAL DRIVE, SUITE 112, ARLINGTON, VA, 22202, US

(21) Appl. No.: 10/718,654

(22) Filed: Nov. 24, 2003

Related U.S. Application Data
(60) Provisional application No. 60/428,909, filed on Nov. 26, 2002.

(51) Int. Cl. H05K 7/14

(52) U.S. Cl. 361/796

(57) ABSTRACT

An articulated backplane retainer system for electronic cards containing rigid and flexible domains. A rigid domain may be connected in some embodiments to an appended rigid domain carrying a connector for additional card. Brackets borne by the rigid domain may be used for ruggedizing the card-connector-rigid domain structure. Further ruggedization may be obtained by swivel connection between a rigid domain and an appended rigid domain. To further mechanically secure and limit the flexible backplane of the invention, a chain link member is provided for connecting flexibly pairs of rigid domains.

### CROSS REFERENCE TO RELATED APPLICATION

This application is based upon U.S. Provisional Patent Application No. 60/428,909, filed Nov. 26, 2002, entitled “ADAPTIVE BACKPLANCE SYSTEM FOR ELECTRONIC CARDS”, which is currently pending.

### FIELD OF THE INVENTION

The present invention relates generally to electronic board packaging systems. More specifically the invention concerns a system for debugging and integrating bus-based cards such as CompactPCI in which a transition card facility is supplemented. The invention also concerns an adaptive backplane system that can fit in space constrained locations.

### BACKGROUND OF THE INVENTION

Printed circuit boards (PCBs) are used for interconnecting, mounting and packaging electronic components such as integrated circuits. The boards (cards) can be arranged in card cages which provide a constructional framework for sets of cards. This is illustrated schematically in FIG. 1, which is a configuration typical of CompactPCI standard card cages and to which reference is now made. Backplane, (referred to also as motherboard) 10 is disposed within card cage 12. Backplane 10, bears eight connectors 14, unto which boards can be plugged.

A plug-in card is connected to the backplane as described schematically in FIG. 2A to which reference is now made. Male connector 16 harbors the female connector 18 onto which the board 20 is affixed. In the CompactPCI connectors, as described in FIG. 2B. Male connector 22 contains pins 24 which accomplish the electric connection between the card (not shown) and the backplane to which it is plugged.

Owing to the compact configuration standards of the backplane system such as in the VME and in the CompactPCI (cPCI), the access to any location on the plugged-in board, except for peripheral sites, is difficult. Probes of test equipment have to be physically connected to specific terminals on the plugged-in boards, typically disposed in card cages. For developers of hardware systems the accessibility to components and test points on the cards is an exceptionally important issue, primarily for debugging of the circuits and their integration with the software. Three strategies for enhancing the accessibility into such cards are presently employed:

1. Leaving vacant connectors in standard card cages. Such an undertaking leaves more room for probes to be connected to the cards' components and test points. The extra accessibility is gained however at the cost of empty connector, which downgrades system integration capabilities.

2. Installing dedicated debugging ports and test points on the cards, which are relatively easily accessible through the front panel, even when installed in card cages.

3. Using card cages dedicated for ease of accessibility.

A previously employed strategy, namely the extender card arrangement, is no longer popular among developers. This disinclination stems from the significant influence that such an arrangement has on signal integrity, and from the limitation on bug reconstruction that such an arrangement confers.

Some backplane systems use a supplementary set of card slot in the rear side of the backplane as is schematically shown in FIG. 3 to which reference is now made. On both surfaces of backplane card are arranged male connectors.

### BRIEF DESCRIPTION OF THE DRAWINGS

FIG. 1 is a schematic prior art description of a backplane card disposed within a card cage;

FIG. 2A is a schematic isometric description of a plugged-in card in a prior art connector of a backplane card;

FIG. 2B is a schematic description of a connector of a backplane showing the arrangement of pins in a connector of a backplane of the prior art;

FIG. 3 is a schematic description of a backplane system of the prior art containing two set of connectors on both sides of the backplane;

FIG. 4 is a schematic isometric view showing a bent flexible card of the invention;

FIG. 5 is a schematic description of a portion of a backplane card of the invention with supplementary cards;

FIG. 6 is a schematic enlarged view of a backplane system of the invention showing an appended rigid domain and plugged in cards;

FIG. 7A is a schematic description of a rigid domain pair of backplane system of the invention;

FIG. 7B is a schematic enlarged view of the connection between the rigid domains of a rigid domain pair of the invention;

FIG. 8 is a schematic view of a ruggedized section of an ABP of the invention, showing brackets;

FIG. 9 is a schematic view of a section of an ABP showing two rigid domain pairs showing the folded layers connecting the appended rigid domains with the backplane rigid domains;

FIG. 10A is a schematic description of a swivel connection between backplane rigid domain and an appended matching rigid domain;

FIG. 10B is a schematic description of a swivel connection between backplane rigid domain and an appended matching rigid domain, with the pivot drawn out;

FIG. 11A is a schematic description of a link connector aligned with a swivel connection and the pivot thereof drawn out on its axis;

FIG. 11B is a schematic description of a link connector in a near attached position;

FIG. 12A is a schematic side view description of a backplane system of the invention, wherein link members are interconnected;

FIG. 12B is a schematic side view description of a backplane system of the invention, wherein link members are interconnected and some rigid domains have moved with respect to their positions as described in FIG. 12A;

FIG. 13 is a schematic description of the applicable electrical connection schemes between matching rigid domains in accordance with the present invention;

FIG. 14 is a general description of a backplane system of the invention including cards and supplementary card, showing ejectors and legs.

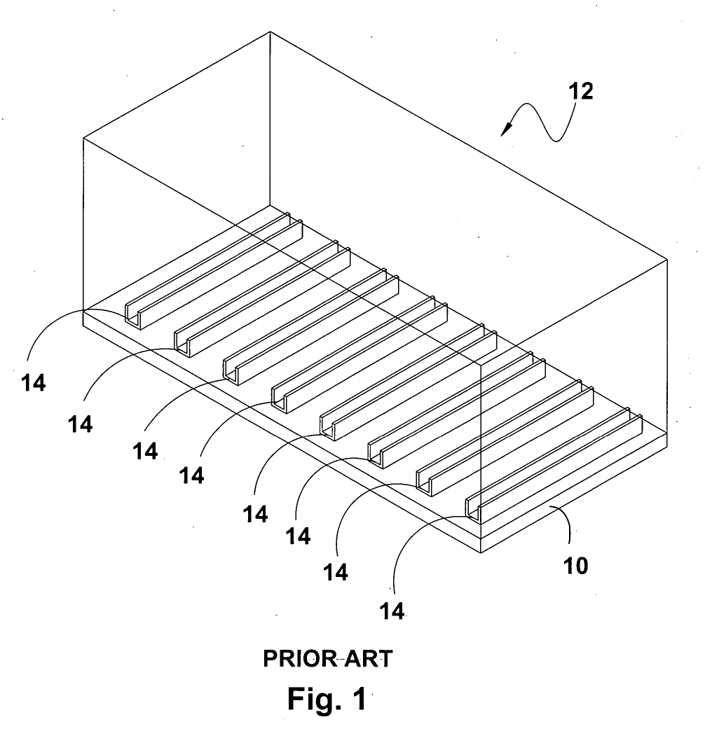

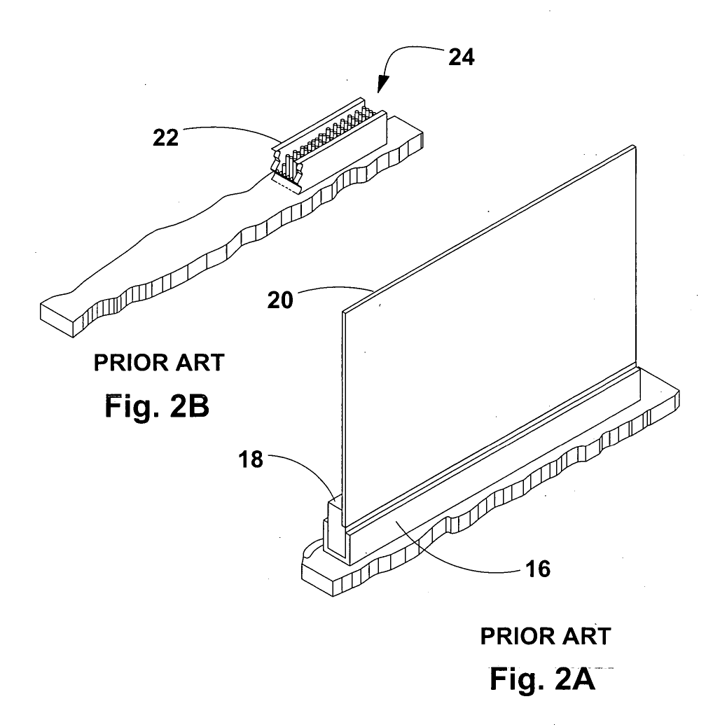

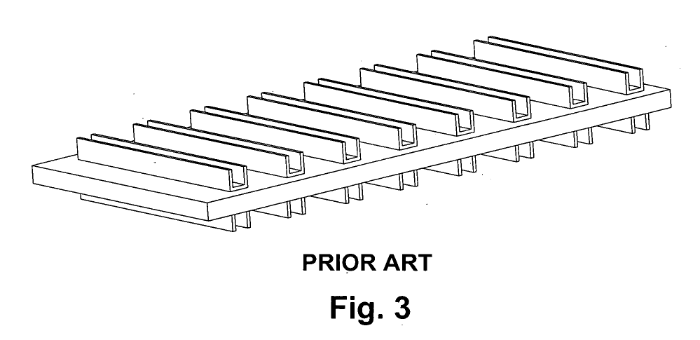

### SUMMARY OF THE INVENTION

The present invention provides an articulated electronic card retainer system that can be implemented in a bus-based card-caged systems such as VME or CompactPCI electronic card standards. The mechanical flexibility of the system allows relative easy access to components and test points on the plug-in cards.

In one embodiment of the present invention, a bracketed plug-in card provides a mechanical strengthening benefit. The bracket stabilizes mechanically the connection between the plug-in card and the backplane, a connection which is subjected to excessive mechanical strains in the flexible backplane.

In accordance with one aspect of the present invention, a mechanically enhanced, flexible backplane in the form of an articulated PCB (printed circuit board)is provided. Typically a backplane system of the invention implements a set of transition cards, connected to the PCB by a matching set of connectors carried by rigid domains. To further mechanically secure the flexible backplane of the invention, a chain link member is provided, for connecting mechanically rigid domain pairs and facilitate a secure yet relatively free relative movement of the two members of the pair.

### DETAILED DESRIPTION OF THE PRESENT INVENTION

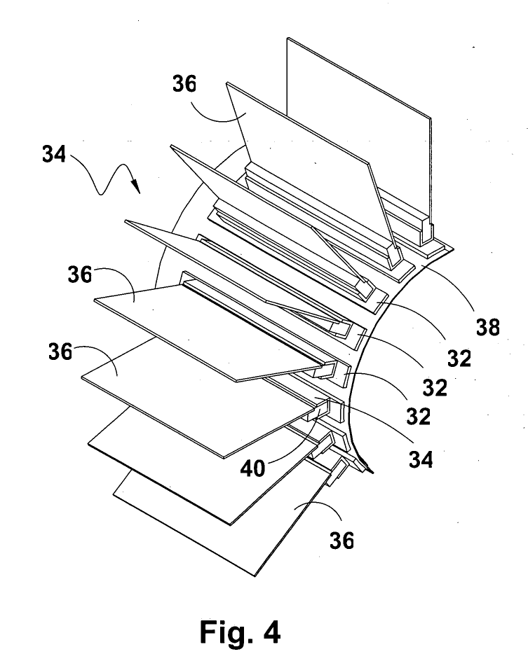

In accordance with the present invention, an articulated backplane (ABP) is provided, in which rigid domains bearing the male backplane connectors, alternate with flexible inter-connector domains (FD). This conformation is better explained in reference to FIG. 4 which illustrates schematically a ABP generally designated 30 in accordance with an embodiment of the invention. Rigid members (RM) 32 of the PCB bear each a male connector 34 which is capable of harboring a compatible electronic card such as cards 36. Besides the rigid domains, the card of the invention includes at least one flexible domain 38. Male connector 34 harbors a female connector 40 onto which the card 36 is affixed. The geometrical dimensions and electrical properties of the connectors and the space between them are defined by the appropriate standard, such as VME, or CompactPCI and must not impair signal integrity.

The FDs are flexible due to their reduced thickness and their constitution. For example, the RMs of the invention are made, typically, like common PCBs, of 6-32 layers of rigid fiberglass typically impregnated with epoxy or polyimide. The FD is made of 2-32 layers of flexible plastic resin, typically Kapton® polyimide with no fiberglass reinforcement.

VME and cPCI Backplane Card Architecture

The present invention provides an electronic card retainer that can be implemented in any bus-based card-caged systems such as the above electronic card standards. The mechanical flexibility of the system allows the developer to gain relative easy access to components and test points on the plug-in cards. For this reason, the system of the present invention is particularly beneficial for those developers who occasionally or frequently have a need for probing the components and test points on the cards in the course of development and integration of bus-based, card-caged systems.

In one embodiment of the present invention, a bracketed plug-in card was described which provided a mechanical strengthening benefit. The bracket stabilizes mechanically the connection between the plug-in card and the backplane, a connection which is subjected to excessive mechanical strains in the flexible backplane.

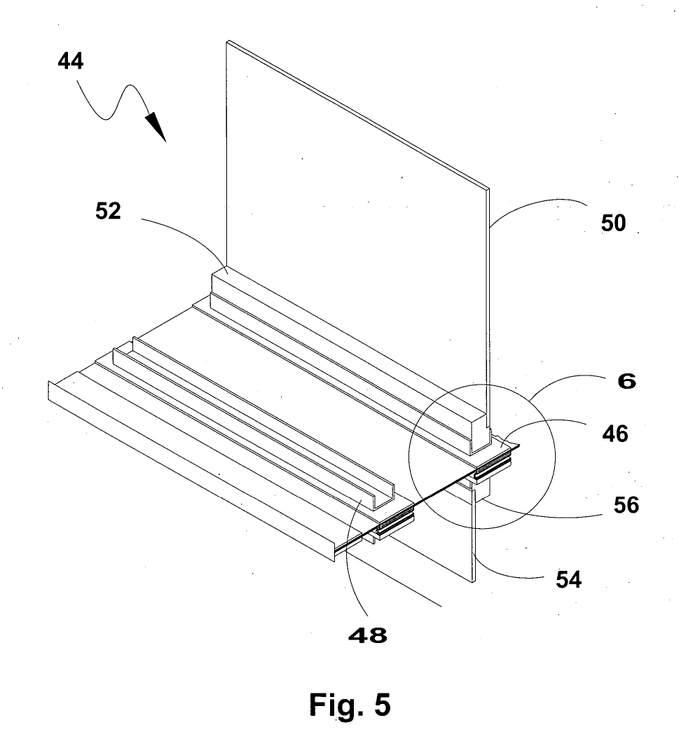

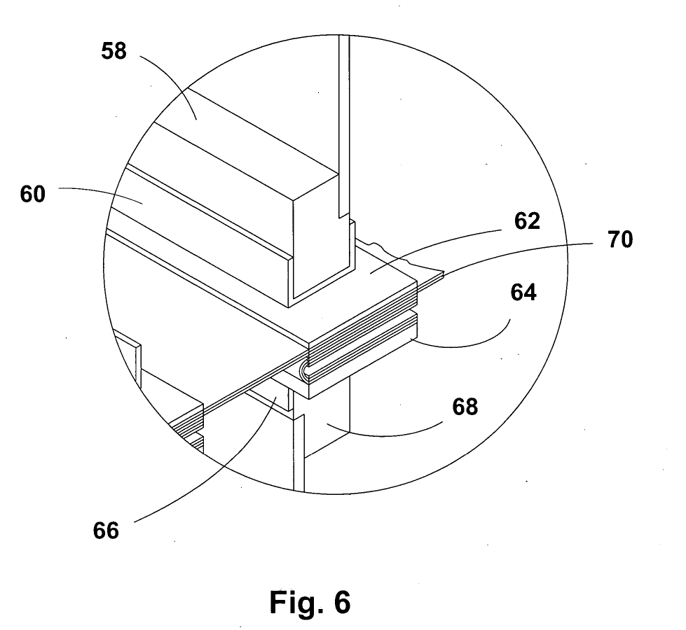

In accordance with one aspect of the present invention, a mechanically enhanced, flexible backplane (ABP) in the form of an articulated PCB (printed circuit board) is provided. Typically a backplane system of the invention implements a set of transition cards, connected to the PCB by a matching set of connectors. The architectural features of this aspect of the invention are better explained with reference to FIG. 5. The ABP 44, of which only a portion is shown, includes rigid domains (RDs) such as RD 46, onto which connectors, such as connector 48 are affixed. A plug-in card 50 is inserted into the respective RD, through mating connector 52 to which the plug-in card 50 is attached. In the other side of the ABP, a transition card (TC) 54 is inserted into the respective RD through connector 56. The configuration of the ABP of the invention at the level of the RDs is better explained with reference to FIG. 6, which is an enlarged schematic view of the connection between plug-in cards and the RDs. Connector 58, is plugged in connector 60 which is affixed to a backplane rigid domain (BPRD) 62. An appended rigid domain (ARD) 64 bears a connector 66 into which a matching card connector 68 is plugged.

The Electric Connections between the BPRD and the Matching ARD

As can be seen in FIG. 6, each BPRD contains a set of continuous layers 70 running through the BPRDs of the ABP. In accordance with a preferred embodiment of the invention, the BPRD contain two sets of flexible layers. The connection between the ARDs of the ABP is maintained by the circuits associated with the layers out of which the ABP is made. Some of the layers contain the circuits which maintain the electric connections between the ARDs and connection to the ports and other connections on the ARD on the ABP.

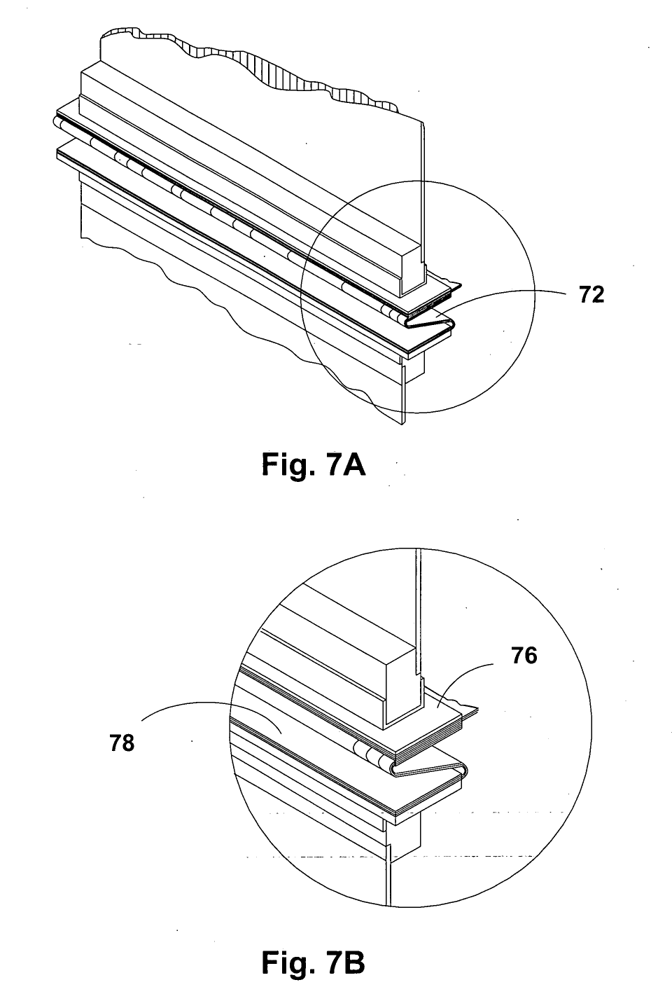

In FIG. 7A to which reference is now made, the layers 72 are folded in a different folding scheme. This folding scheme allows more flexibility of the supplementary card positioning relative to the BPRD and associated card. In FIG. 7B an enlarged view of the folding scheme shows how the flexible layers are folded connecting opposite sides of the front and rear ARDs. The relationship between BPRD 76 and the ARD 78, Which constitute a rigid domain pair is such that their relative movement is more slack than in the tighter folding schemes.

Plug-in Board Brackets and Ruggedization

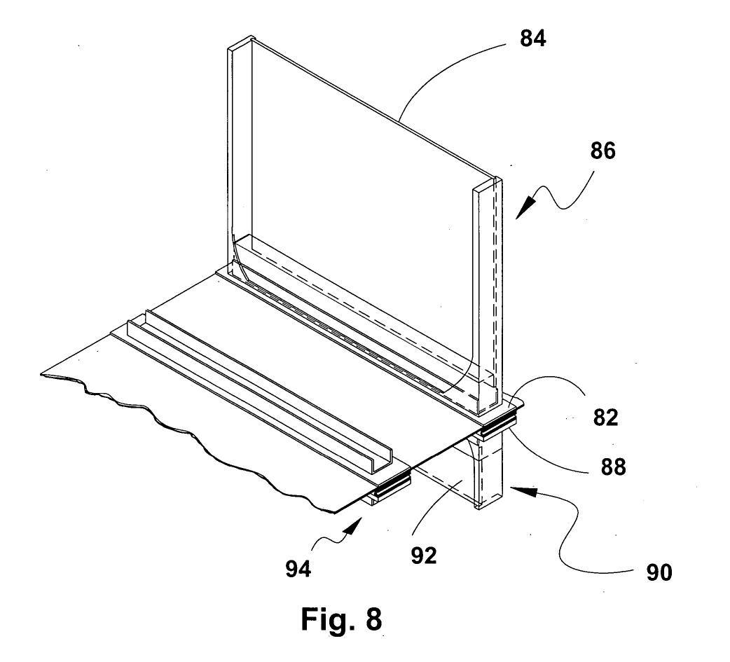

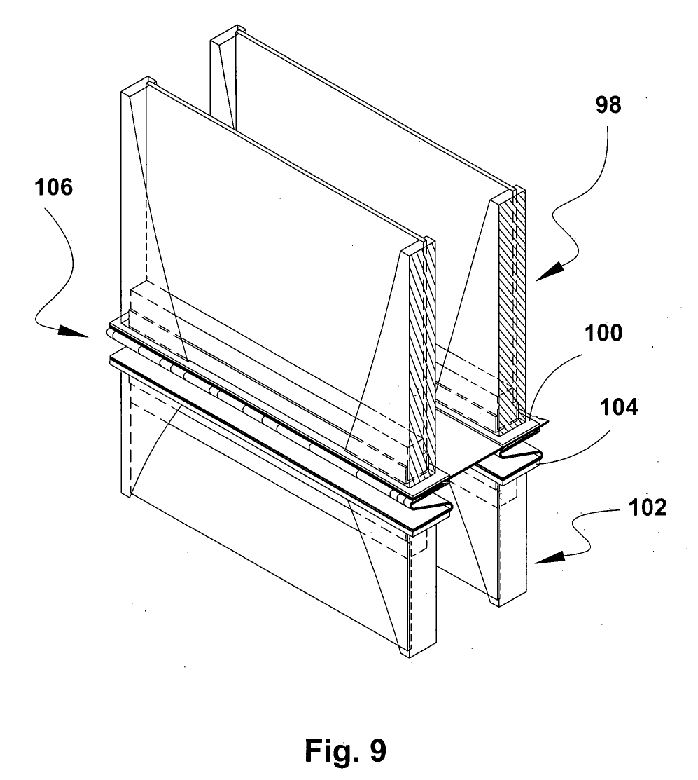

In FIG. 8 to which reference is now made, a BPRD 82 into which a plug-in card 84 is installed is fitted with a bracket 86. The ARD 88 is also fitted with bracket 90, which corresponds in length with the height of plug-in card 92. The adjacent RD pair 94 is shown without plug-in cards and brackets. In FIG. 9 to which reference is now made, two adjacent RD pairs of a ABP are shown. Bracket 98 is applied to BPRD 100 and another bracket 102 is applied to the respective ARD 104. An adjacent RD pair 106 is connected by a flexible domain to BPRD 100.

Mutually Securing the BPRD and the Matching ARD

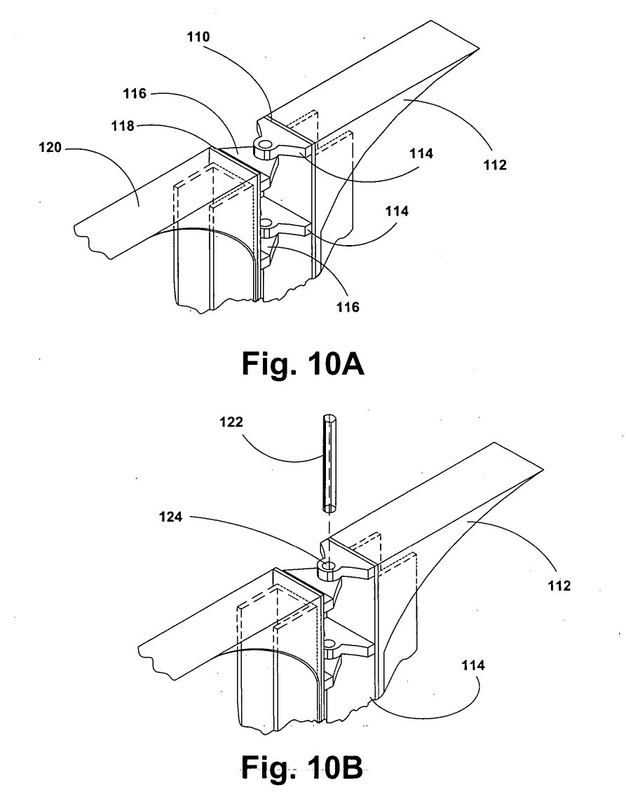

To enhance the ruggedness of the backplane system of the invention, yet keep it flexible for convenient access into the plugged-in boards, further measures are taken. In FIG. 10A to which reference is now made, another aspect of the invention is described schematically in which a swivel connecting between a BPRD and the matching ARD is provided. Accordingly, to ARD 110, associated with bracket 112, are attached swivel members 114. Swivel members 114 are each pivotally fitted to the matching swivel members 116, which are attached to BPRD 118. Bracket 120 is associated with BPRD 118. In FIG. 10B the same construction is shown, with the pivot 122 drawn out along its axis out of the pivot's bore 124. Pivot 122 locks the two members of the RD pair together allowing rotational movement around the pivot.

Stretch and Twist Limiter Chain

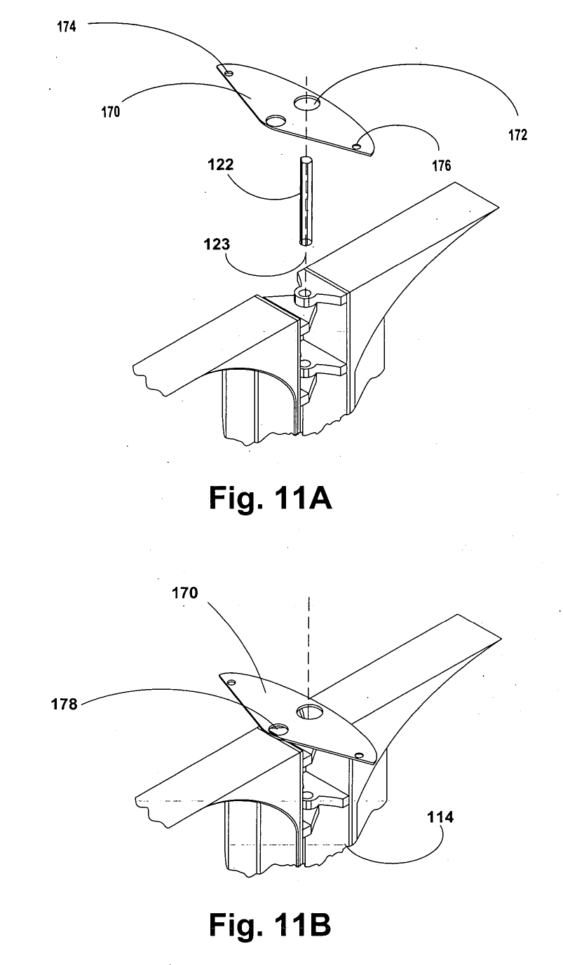

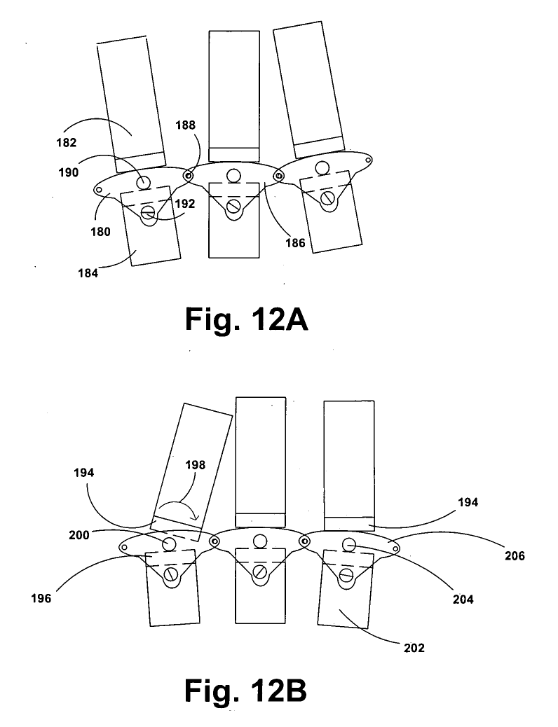

To further mechanically secure the flexible backplane of the invention, a chain link member is provided. From the interlinked plurality of which links a mechanically securing chain is made. The chain thus applied provides a limit to the twist and stretch that can be imposed on the backplane of the invention. To describe the limiter chain, reference is now made to FIG. 11A. Link member 170 contains four holes, of which 172 is used for driving a fastening means such as a rivet to pivot 122, shown drawn out on its axis 123. The two lateral holes 174 and 176 are used for pivotally connecting the link member 170 to adjacent link members (not shown). In FIG. 11B the link member 170 is shown in a near fastened position, whereby the link member 170 is approached to the RD pair for locking. Hole 178 is used for fastening link member 170 to the pivot (not shown). FIG. 12A is a schematic side view of a portion of a backplane of the invention, with the link members such as link 180 installed. The link member 180, is disposed between the pair members BPRD 182 and ARD 184. Link 180 is connected pivotally to link member 186 at hole 188, such that a relative rotational movement between the link members can be achieved. Each member of the RD pair, for example ARD 180 and BPRD 182 cane perform relative rotational movement around the axis 190. In a preferred embodiment of the invention, the link members such as link member 180, are fixed to one bracket of the RD pair. This is fixation is typically performed by affixing element such as a rivet or a screw 192.

The relative movement of the two members of the RD pair is further described in FIG. 12B to which reference is now made. BPRD 194 and ARD 196 constitute a rigid domain pair (RD pair). BPRD 194 has moved in the direction of arrow 198 around pivot 200, whereas ARD 196 has remained static with respect to the pivot 200. ARD 202 turns around pivot 204 together with link member 206, to which it is attached.

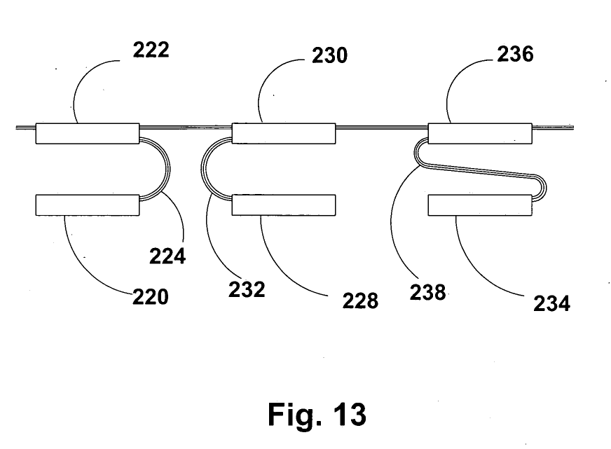

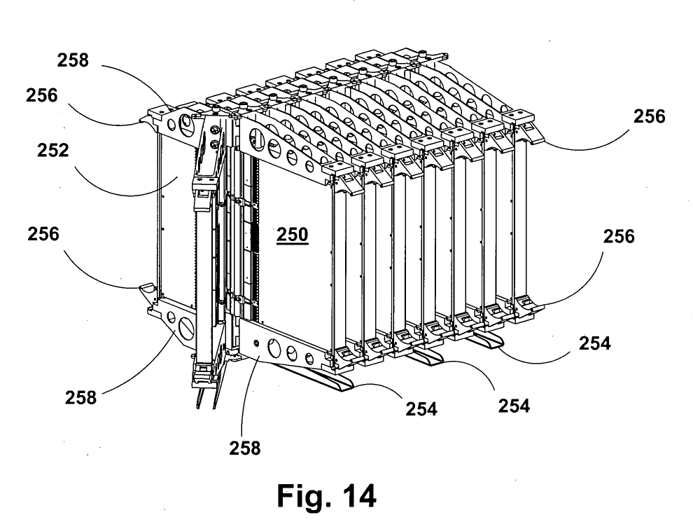

In FIG. 13 a schematic description of the applicable connecting schemes between matching rigid domains. ARD 220 and BPRD 222 constitute a rigid domain pair. The electrical connection between the two members of the pair is maintained through a right side flexible connection 224. ARD 228 and BPRD 230 constitute another rigid domain pair, in this pair the electric connection is maintained through a left side flexible connection 232. In another rigid domain pair, ARD 234 and BPRD 236 are interconnected by a folded flexible connection 238. In FIG. 14 to which reference is now made, a complete system of a backplane and included front or main cards such as card 250, and rear supplementary cards such as card 252. Legs 254 support the backplane system, providing stability which is required in the course of handling and probing the backplane system. Ejectors such as ejectors 256 are required for retrieving the plugged cards. The cards which are forcibly pushed into the multi-pin connector are ejected usually by applying a force provided by the leveraging of the ejectors. In accordance with the present invention, each injector is pivoted on a bracket pivot thereby facilitating forceful retrieval of the card.

The mechanical flexibility of the backplane system of the invention is nevertheless an advantage that can be used for applications in which space is a very limited such that bending or convoluting a backplane system may become useful. Such extreme requirements for space are typical of vehicles, especially of aerospace carriers, as well as in ships and submarines and ships. To fully express the utility of the flexible backplane as a flexible structure for either handling or for permanent deployment, a flexible card cage is advantageously used. The flexible card cage, which may be articulated, can be bent or convoluted, yet provide the backplane system an external protection.

1. An articulated backplane electronic card retainer, comprising:
at least two rigid domains traversing the backplane, and
flexible domains flanking at least both sides of said rigid domain.

2. An articulated backplane electronic card retainer as in claim 1 further comprising at least one card bracket connected to at least one rigid domain for ruggedizing said card retainer.

3. A mechanically strengthened articulated flexible backplane system, comprising:
at least one bracket for at least a plugged-in board, wherein said bracket is connected to a rigid domain of said backplane; and
a pivot locking together pivotally members of a rigid domain pair.

4. A mechanically strengthened articulated flexible backplane system as in claim 3 further including an appended rigid domain per at least one rigid domain, forming a rigid domain pair.

5. A mechanically strengthened articulated flexible backplane system as in claim 3 and wherein said system is ruggedized further by having a link member interconnecting two adjacent members of said at least one rigid domain pair.

6. A method for ruggedizing an articulated electrical backplane system whereby each rigid domain further includes an appended rigid domain unto which supplementary cards can be plugged in, and wherein at least one of said rigid domains is fitted with brackets, and wherein each rigid domain having an appended rigid domain is interconnected with said appended rigid domain.

7. A method for ruggedizing an articulated electrical backplane as in claim 6 whereby each rigid domain further including an appended rigid domain unto which supplementary cards can be plugged in, and wherein each rigid domain having an appended rigid domain is interconnected with another rigid domain having a respective appended rigid domain.
